(19) United States
(12) Patent Application Publication
(10) Pub. No.: US 2016/0282139 A1
(43) Pub. Date: Sep. 29, 2016

(54) Data Collection Device and Method to Support Multiple Profiles in a Utility Meter System

(71) Applicant: Telefonaktiebolaget LM Ericsson (publ), Stockholm (SE)

(72) Inventors: Kirti Girdhar, Gurgaon (IN); Sandeep Akhouri, New Delhi (IN); Enrico Brancaccio, Milano (IT); Sumit Singhal, Gurgaon (IN)

(21) Appl. No.: 15/079,780

(22) Filed: Mar. 24, 2016

(30) Foreign Application Priority Data
Mar. 27, 2015 (IN) 0341/KOL/2015

(51) Int. Cl. G01D 4/00; G01R 21/133

(52) U.S. Cl. CPC G01D 4/002; G01R 21/133

(57) ABSTRACT

The present disclosure generally relates to the field of utility meter systems. More specifically, the present disclosure relates to a technique of managing and storing multiple utility consumer profiles, each of the profiles being identifiable by a unique personal identifier of the respective utility consumer, in order to associate data from one or more utility meters to one of the profiles and to store the associated data. A corresponding data collection device, utility meter system and method of data collection in a utility meter system are provided. The method comprises managing multiple utility consumer profiles, receiving data from one of a plurality of utility meters, associating the received data to one of the profiles, and storing the associated data in a memory.

### TECHNICAL FIELD

The present disclosure generally relates to the field of utility meter systems. More specifically, the present disclosure relates to a technique of collecting data from a plurality of utility meters with respect to consumer profiles.

### BACKGROUND

A utility system provides a utility, such as electricity, gas, or water, to utility consumers via a corresponding distribution system. A utility consumer can be a household, a commercial entity or any other facility consuming one or more utilities. Each facility is provided with at least one meter, such as a power or current meter, gas meter or water meter, which measures the respective utility consumption. The utility provider will periodically read the meter data, in order to bill the utility consumer.

A known utility meter system is illustrated in FIG. 1a in form of a schematic block diagram. Such utility meter system may include a plurality of facilities, each of which consumes a utility and, therefore, is equipped with one or more meters for the respective utility. In the illustrated system two complexes 110 and 120 are illustrated, each of which comprises a plurality of facilities. Such facilities can be a household or a commercial building. The utility meters of each of these facilities are connected within the complex, for example, via a communication network. As is illustrated with respect to complex 110, the metering equipment is connected to an access point 115 for further data communication outside of the complex 110. For instance, the access point 115 is capable of establishing a data communication with a network 130. Via network 130, the access point 115 can start a data exchange session with a head end system 140. Such head end system is also referred to as an advanced meter reading system (AMR system).

The complex 120, on the other hand, is provided with utility meters or metering equipment, each of which is capable of establishing a data connection to head end 140 via network 130. Such data connection may be established via a mobile telephone provider network, such as a GSM network.

According to such a head end system, a utility provider may collect meter data via head end 140. For instance, an entity of/at the head end system 140 may establish a connection to access point 115 to request/read data from each of the meters connected to access point 115. Similarly, the entity of the head end system 140 may connect to each of the utility meters within complex 120 via network 130 to request/read the respective meter data.

A known way of communicating between the head end system 140 and the metering equipment within complexes 110 and 120 is the “Device Language Message Specification” (DLMS). The data exchange can be conducted according to the “Companion Specification for Energy Metering” (COSEM).

A corresponding data exchange model is illustrated schematically in FIG. 1b. On the right hand side of this figure a plurality of metering equipment is depicted. Each of this metering equipment acts as a server, since it provides meter data. According to the COSEM standard metering equipment is modelled as a set of logical devices. Each logical device models a subset of the functionality of the metering equipment as these are seen through its communication interfaces. Various functions can be modelled using COSEM interface objects.

On the left hand side of FIG. 1b, the client side of the system is depicted. Such data collection system acts as a client, since it requests data from the metering equipment. In order to retrieve meter data from the complexes 110 and 120, an entity at the head end system 140 associates with the access point 115 or with each individual utility meter in complex 120. After sending a request from the head end system 140 to each single utility meter, the respective meter transmits the requested data back to the head end system 140. Thereafter, the association can be released. While this reading of the meter data can be conducted at any time and without interaction of a user being physically at the meter, the utility provider can easily gather meter data, whenever required. However, such known AMR systems still have disadvantages.

### SUMMARY

Accordingly, there is a need for an improved technique for reading meter data.

According to a first aspect, a data collection device for use in a utility meter system is provided. The data collection device comprises a data communication circuit configured to receive data from one of a plurality of utility meters, a memory configured to store data, and a data processing circuit. The data processing circuit is configured to manage and store multiple utility consumer profiles, each of the profiles being identifiable by a unique personal identifier of the respective utility consumer. The data processing circuit is further configured to associate the received data to one of the profiles and to write the associated data into the memory.

In other words, a utility consumer profile for each utility consumer can be generated and data of one or more utility meters can be associated with each of these profiles. Managing one user profile per utility consumer provides the utility provider(s) an easy handling of utility meter data by decoupled the data from the actual physical utility meter. When implementing the data processing in software, consumer profiles can easily be ported in case of a utility consumer moving from one location to another. New consumer profiles can be easily be added, deleted and updated dynamically. Also the consumption of multiple utilities can be associated with one user profile, so that the utility provider can provide the consumers with improved utility consumption reports capturing details of the consumption of each utility in one report. Furthermore, a highly itemized utility consumption report can also be generated capturing details of multiple facilities (homes and/or commercial units), so that utility consumption reports can be provided including details, such as which facility or group of facilities consumed how much.

The data processing circuit may further be configured to initiate the reception of data from the one utility meter by the data communication circuit. For instance, the data processing circuit can send a request signal or message via the data communication circuit to one or more of the plurality of utility meters, in order to receive the respective data from the meter(s). This request can be send to the utility meter(s) on a periodic basis or arbitrarily. Alternatively, the utility meter(s) periodically or randomly send their respective data to the data collection device.

Associating the utility meter data to one of the profiles may be conducted in that the data processing circuit is configured to generate at least one COSEM object including the received data and map the COSEM object to the personal identifier. By using COSEM objects mapped to a personal identifier, even legacy systems already operating according to COSEM can be integrated into such new utility meter system.

The data communication circuit is further configured to transmit the associated data stored in the memory to a head end entity of the utility meter system. This data transmission can be performed under the control of the data processing circuit. Furthermore, the data communication circuit is configured to transmit the associated data to the head end entity upon receiving a request for the associated data from the head end entity. Such request from the head end entity may include the personal identifier of at least one utility consumer. At any time, the head end entity can request utility meter data by simply providing one or more personal identifiers of the utility consumers to the data collection device. Thus, whenever required, the head end entity can access the data collection device and retrieve utility meter data per user profile. This allows a very flexible way of retrieving utility meter data, i.e. data per utility consumer, while having the flexibility of requesting utility meter data for one or a plurality of user profiles at the same time.

The data processing circuit is further configured to parse the request, to determine the at least one personal identifier, and retrieve the associated data from the memory based on the determined at least one personal identifier. Thus, the request for utility meter data can be handled at the data collection device with only a few processing steps for retrieving the associated data from the memory.

Furthermore, the data processing circuit is configured to determine whether data associated with the personal identifier included in the request is stored in the memory. In case the data is not stored in the memory, the data processing circuit controls the data communication circuit to retrieve the data from a corresponding utility meter out of the plurality of utility meters. The utility meter can be identified via the user profile managed and stored in the data collection device based on the received personal identifier. Thus, in case the head end entity requests meter data for a user profile, where the meter data is not (yet) available at the data collection device, the retrieval of such data from the utility meters can be triggered by the same request from the head end entity as for “usual” data requests. In case that the requested data is stored in the memory, the data processing circuit simply reads the associated data from the memory and transmits it to the head end entity via the data communication circuit.

The received data is utility meter data representing a consumption of electric power, gas and/or water. Even a combination of such utility meter data can be collected and associated with a single user profile. When requesting the data by the head end entity, the entire utility meter data of one or more utilities can be provided to the head end entity. Alternatively, the request of the head end entity may specify which utility meter data of the user profile is requested.

The personal identifier can be a phone number of the utility consumer, a mobile station international subscriber directory number (MSISDN) of the utility consumer or a public internet protocol (IP) address of the utility consumer. In any case, the personal identifier is a key that can be used to uniquely identify the user profile within the data stored in the data collection device. Of course, the present disclosure is not limited to the above-mentioned personal identifiers. For instance, a social security number, a company registration or similar uniquely identifying keys can be used. The data collection device may even store more than one personal identifier for each consumer profile. This allows different head end systems (e.g. of different utility providers) to request data from the data collection device based on different personal identifiers. As long as the personal identifier uniquely identifies the consumer, it can be used within the data collection device according to the present disclosure.

According to another aspect, a utility meter is provided that comprises the data collection device as outlined above. Thus, the data collection device may be integrated into a utility meter. In case of a facility housing multiple consumers, such as a residential complex, one utility meter may be equipped with a data collection device collecting the utility meter data per user profile from the remaining meters in the facility. Alternatively or additionally, the data collection functionality is installed in a meter as corresponding software.

According to another aspect, a head end system is provided that comprises the data collection device as outlined above. Thus, the data collection device forms an entity of the head end system. Again, the data collection device may be implemented in the head end system as software.

According to a further aspect of the present disclosure, a utility meter system is provided. Such utility meter system comprises a plurality of utility meters, a head end system and a data collection device as outlined above. Additionally, the head end system can be configured to start and end a data request session with the data collection system. Such session is bound to at least one personal identifier identifying at least one respective utility consumer for whom data is to be requested. In other words, the head end system acts as a client associating with the data collection system, requesting data after a successful association and releasing the association (session). When associating, i.e., starting a session, the head end system can bind this session to the at least one personal identifier. Alternatively, the head end system may start a general session and provide the respective personal identifiers to the data collection system when requesting utility meter data from the data collection system.

Furthermore, the head end system and the data collection device are configured to communicate according to the DLMS standard. Of course, the present disclosure is not limited to the DLMS standard and other standards and protocols can be used to set up sessions, request data etc. between the systems and devices.

The data collection device can collect data of utility meters installed in one residential complex or a commercial complex. The utility meter system according to the present disclosure is not bound to the physical utility meter devices or to a particular area, region, building complex, etc. When implemented as a software application, the data collection can take place on any device which can communicate with one utility meter or any group of utility meters independent of their physical location.

According to a further aspect of the present disclosure, a method of data collection in a utility meter system is provided. The method comprises managing multiple utility consumer profiles, each of the profiles being identifiable by a unique personal identifier of a respective utility consumer. Furthermore, the method comprises receiving data from one of a plurality of utility meters, associating the received data to one of the profiles, and storing the associated data in a memory.

The method may include initiating the receiving of data from the one utility meter. For instance, a request signal or message can be send to one or more of the plurality of utility meters, in order to subsequently receive the respective data from the meter(s). This sending of a request to the utility meter(s) can be conducted on a periodic basis or arbitrarily. Alternatively, the utility meter(s) periodically or randomly send their respective data for reception.

The associating of the data can comprise generating at least one COSEM object including the received data and mapping the COSEM object to the personal identifier. With or without using COSEM objects, the method can further comprise transmitting the associated data to a head end entity of the utility meter system.

Furthermore, the method may also comprise receiving a request for the associated data from a head end entity, where the request includes the personal identifier of at least one utility consumer. After receiving such request, the request can be parsed, the at least one personal identifier can be determined from the request, and the associated data can be retrieved from the memory based on the determined at least one personal identifier. In other words, the method comprises searching within the data received with the request for at least one personal identifier and reading data from the memory that is associated to user profiles identified by the found personal identifiers.

The method can further comprise determining whether meter data associated with the personal identifier included in the request is stored in the memory, and if the meter data is not stored in the memory, retrieving the data from a corresponding utility meter out of the plurality of utility meters. Thus, if the data is not available within the memory, a real-time fetching of utility meter data can be initiated.

The data received from one of a plurality of utility meters is utility meter data representing a consumption of electric power, gas and/or water. Thus, not only one of these utilities and the respective consumption can be associated to a user profile, but also a combination of such utility consumptions.

According to a further aspect, a computer program product is provided that comprises program code portions for causing the steps of any one of the method aspects described herein to be performed, when the computer program runs on a computer system or on one or more computing devices. The computer program may be stored on a computer-readable recording medium or may be downloadable as a signal.

Thus, the method aspects described herein can be performed solely in form of software applications. This allows for cost effective software upgrades instead of hardware upgrades, i.e., the exchange of old utility meters with new ones. It further allows a dynamic addition, deletion and update of consumer profiles. Thus, a more on-demand consumption and billing system can be established.

In general, the steps of any one of the method aspects described herein may equally be performed in one or more suitable components, devices or units, e.g. in suitable components of a utility meter, separate data collection device, head end entity or other device provided in a utility meter system.

### BRIEF DESCRIPTION OF THE DRAWINGS

In the following, the present disclosure will further be described with reference to exemplary embodiments and examples illustrated in the figures, in which:

FIG. 1a is a schematic illustration of a known utility meter system;

FIG. 1b is a schematic illustration of a known COSEM object model;

FIG. 2 is a schematic illustration of an embodiment of a utility meter system;

FIG. 3 is a block diagram schematically illustrating a data collection device (e.g. multi-profile meter device);

FIG. 4 is a flow chart illustrating a method embodiment performed in the data collection device of FIG. 3 or a software running on any device within the utility meter system of FIG. 2; and

FIG. 5 is a block diagram schematically illustrating an interaction between a head end system and a data collection device (multi-profile meter).

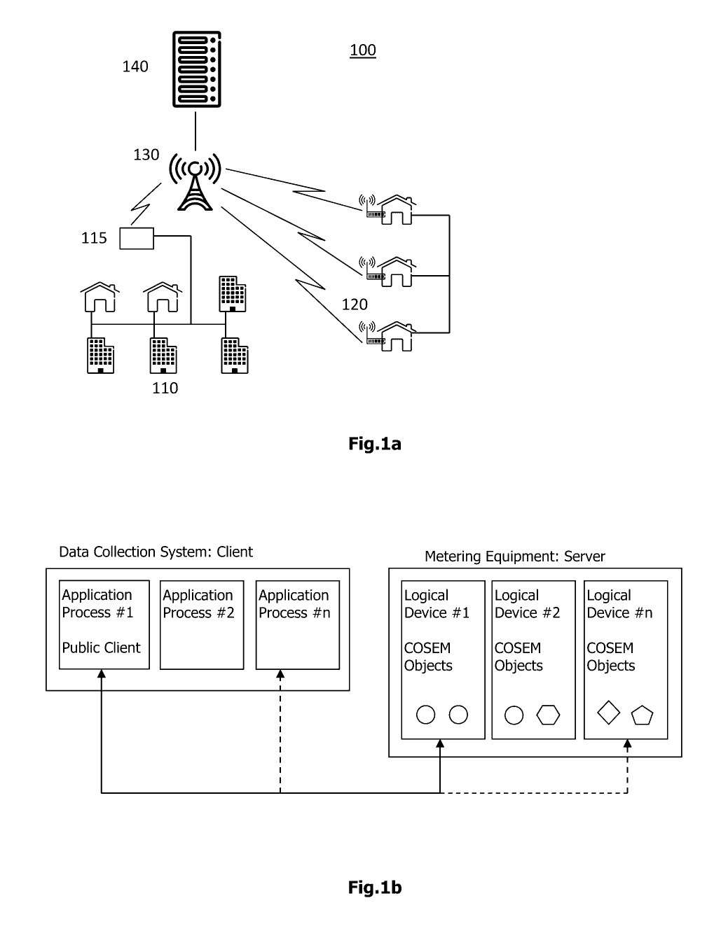

### DETAILED DESCRIPTION

In the following description, for purposes of explanation and not limitation, specific details are set forth, such as specific utility meter system topologies including particular network nodes within a utility meter system, in order to provide a thorough understanding of the present disclosure. It will be apparent to one skilled in the art that the present disclosure may be practiced in other embodiments that depart from these specific details. For example, although the present disclosure is described with reference to Device Language Message Specification (DLMS) as a specific example for a transport and application protocol, the present disclosure may be practiced based on any other protocol suitable for data transmission between entities of a utility meter system. Similarly, the present disclosure is described with respect to Companion Specification for Energy Metering (COSEM) as a specific example for modelling metering equipment as a set of logical devices and interface objects. However, the present disclosure may be practiced based on other models of the topology of utility meter system entities and corresponding utility meter data (also referred to as metering data).

Those skilled in the art will further appreciate that functions explained herein below may be implemented using individual hardware circuitry, using software functioning in conjunction with a programmed microprocessor or a general purpose computer, using an application specific integrated circuit (ASIC) and/or using one or more digital signal processors (DSPs). It will also be appreciated that when the present disclosure is described as a method, it may also be embodied in a computer processor and a memory coupled to a processor, wherein the memory is encoded with one or more programs to cause the processor to perform the methods disclosed herein when executed by the processor.

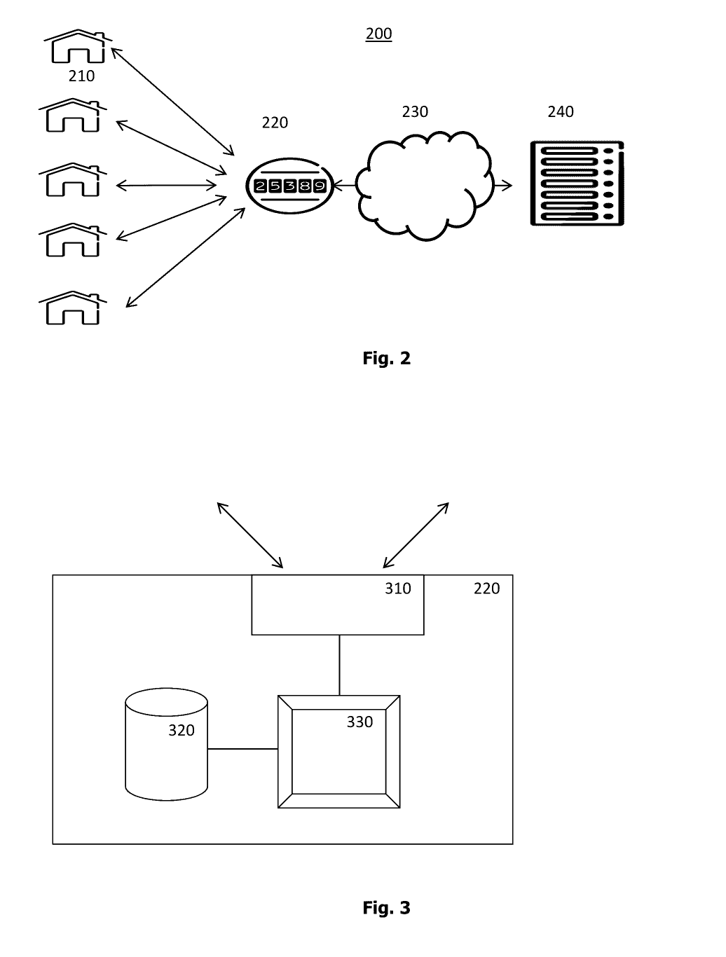

FIG. 2 illustrates an exemplary utility meter system comprising at least one residential or commercial facility, such as a residential unit, commercial unit, household, apartment, commercial complex etc. Each of the facilities is provided with at least one utility meter 210. Each utility meter 210 meters a consumption of a utility, such as electric power, gas, or water. A utility meter may also combine metering consumption of more than one utility, such as gas and water. The present disclosure is not limited to such utility meters 210, but is also applicable with respect to utility meters for other utilities and utility meters metering different combinations of utilities.

The utility meter system 200 further includes a head end system 240. This head end system 240 can communicate with other devices via a network 230. Network 230 is the internet, but can also be any other access technology, such as wireless radio access technologies.

The utility meters 210 are connected to a data collection device 220. Such connection may be based on DLMS and COSEM. Furthermore, the utility meters 210 are connected to data collection system 220 and/or with other utility meters 210 based on a specific network topology. For instance, they may be collected via an Ethernet LAN using TCP/IP and/or UTP/IP based communications. Each utility meter may have its own IP address, either a local or a public IP address. Furthermore, a plurality of utility meters 210 may be connected together and the data collection device 220 is connected to this group of utility meters 210 via an entry point into this network. In any case, the meters can be reached remotely from the data collection device 220. Similarly, the head end system 240 can reach to (conduct a data communication with) each of the utility meters 210 via network 230 and/or data collection device 220.

Alternatively, the utility meters 210 may communicate with each other and with data collection system 220 based on a 3-layer, CO, HDLC (High-Level Data Link Control) based profile. In such case, the address of a physical device on the network is provided by its lower HDLC address. Furthermore, the utility meters 210 may be connected to a bus, for example an RS 485 bus.

The data communication between data collection system 220 and head end system 240 may be provided via a WAN, which can either be a PSTN or a GSM telephone network. The present disclosure is not limited to these networks, but can also rely on other telephone networks, such as UMTS or LTE based networks. Of course any other network can be involved in the data communication between utility meters 210, data collection device 220 and head end system 240.

The utility meters 210 are not limited to a communication with data collection system 220. For instance, each of the utility meters 210 may have an optical port allowing a local data exchange with a handheld unit.

The head end system 240 is capable of starting and ending a data request session with the data collection system 220. Such session is bound to at least one personal identifier identifying at least one respective utility customer for whom data is to be requested.

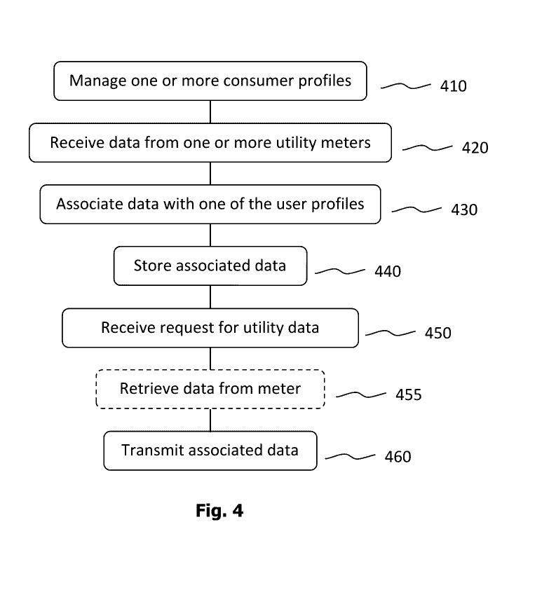

The data collection device 220 is illustrated in more detail in FIG. 3. It includes a data communication module 310, i.e., a data communication circuit, configured to receive data from one of a plurality of utility meters 210. This receiving of data may be initiated by the data collection device 220 on a periodic basis or arbitrarily. Alternatively, each of the utility meters 210 periodically or randomly transmits utility meter data to the data collection device 220.

Data collection device 220 further includes a memory configured to store data. The memory 320 is capable of storing utility meter data, consumer profile data, identification information and addressing information for each of the utility meters 210 as well as data allowing a data communication to and from the head end system 240.

Data collection device 220 further includes a data processing unit 330, i.e., a data processing circuit, that is configured to manage and store multiple utility consumer profiles. Data processing unit 330 comprises, for example, one or more microprocessors, controllers, or the like, and one or more associated memory devices storing computer program instructions for execution by the microprocessor(s), etc. The managing and storing of the consumer profiles may involve the storage of respective profile data within memory 320. Such consumer profiles include at least a unique identifier for the utility consumer corresponding to the consumer profile. Such unique identifier can be a personal identifier, such as a social security number, a phone number of the utility consumer, a mobile station international subscriber directory number (MSISDN) of the utility consumer and a public Internet protocol (IP) address of the utility consumer. The present disclosure is not limited to these unique personal identifiers. However, any unique identifier can be employed with a consumer profile as a key for profile identification. Each consumer profile may be linked to a particular consumer, which can either be a person, a company, or any other legal entity. The present disclosure is not limited to such consumer profiles, but may also employ consumer profiles for groups of people, groups of companies, or any other entity that requires association of specific utility consumption. For instance, while in a residential complex a plurality of utility consumers may each be provided with a respective consumer profile, there may be an additional consumer profile for all or a partial group of consumers to associate a general utility consumption of the residential facility. For example, general power consumption for the garage and the elevator may be metered, or water used in a community garden, etc.

The data processing unit 330 can be configured to generate at least one COSEM object including the received utility meter data and map this COSEM object to the personal identifier. In this manner, the data can be associated with one of the profiles. The data processing unit can then store data tuples consisting of the COSEM object and the personal identifier, i.e., a key of the profile, in memory 320.

The data communication module 310 is further configured to transmit the associated data stored in the memory 320 to a head end entity of the utility meter system, such as an entity of the head end system 240. To do so, the data processing unit 330 may read the data from memory 320 and provide it to data communication module 310 for proper transmission to the head end system 240. The transmission of such data to the head end system 240 may be initiated by a request send from the head end system 240 to the data collection device 220. Such request is received at the data communication module 310 and forwarded to data processing unit 330. The data processing unit 330 then parses the request to determine at least one personal identifier within the request. For instance, head end system 240 may provide one or more personal identifiers for retrieving corresponding utility meter data for the utility consumers identified by these unique personal identifiers. Based on the parsed and determined personal identifier, the data processing unit retrieves associated data from the memory. For instance, the COSEM object(s) for each of the determined personal identifiers (from the request) may be identified within memory 320 based on the above-mentioned data tuples stored therein. The associated data retrieved from the memory 320 can then be forwarded to data communication module 310, in order to transmit such data via network 230 to head end system 240. Either the data processing unit or the data communication module 310 format the data retrieved from memory 320 into a format transmittable to head end system 240. For instance, the data transmission may take place in accordance with DLMS. However, any other data transmission standard and protocol can be used to provide the associated utility meter data to the head end system 240.

In case that the data processing unit 330 cannot retrieve data from memory 320 based on the parsed and determined personal identifier, the utility meter data has first to be retrieved from the utility meter 210. For instance, the data collection device 220 may not have respective utility meter data available, since it was not gathered before. In this case, the data processing unit 330 will send a data request to utility meter 210 via data communication module 310. This request can be based on an identification of the utility meter 210 stored together with the consumer profile. For instance, in the consumer profile at least one utility meter identification may be stored, such as one for the electric power meter, one for a gas meter, and/or one for a water meter. This data may further comprise an address, a protocol, or a standard on how to communicate with the utility meter.

In any case, when the data processing unit 330 has the “real-time” utility meter data at hand, it can transmit it to the head end system 240 in the usual manner. For instance, the data processing unit 330 may generate a COSEM object which is then forwarded to the head end system 240.

The data collection device 220 as illustrated in FIG. 2 is an intermediate device between utility meters 210 and the head end system 240. However, the present disclosure is not limited to this specific intermediate device. For instance, the data collection device 220 may also be an entity at the head end system 240. Furthermore, data collection device 220 may be installed on a smart meter 210, e.g., a utility meter capable of processing program code to perform the method steps of this disclosure. For example, a data collection device 220 as illustrated and described with respect to FIG. 3, may be installed in a smart utility meter 210. In this case, other utility meters 210 which may not have the full capabilities of the smart meter may communicate provide their respective utility meter data to this multi-profile meter 210.

Referring now to FIG. 4, a block diagram of a method according to an aspect of the present disclosure is illustrated. Such method may be performed on a data collection device 220, smart utility meter 210 (multi-profile meter), and/or an entity of the head end system 240. The method begins with the managing of one or more consumer profiles (step 410). Each of the consumer profiles is identifiable by a unique personal identifier of a respective utility consumer. As described herein, the personal unique identifier may be a social security number, telephone number (MSISDN), public IP address, etc. The managing of the one or more user profiles includes the storing of such user profiles. For example, per consumer profile, one or more personal identifiers may be stored together with an identification of one or more utility meters 210. Depending on the consumer profile, one or more utility meters 210 may be associated with the respective consumer profile. Besides an identification of the utility meter 210, a way of addressing such utility meter 210 is also stored. For instance, a network protocol and transmission standard as well as an address of the utility meter corresponding to this network and transmission standard CdO be stored with a consumer profile.

Next, at step 420, data from one of a plurality of utility meters 210 is received. This reception of data may be initiated from a data collection device 220 performing the method according to FIG. 4. However, the data may independently be sent from a utility meter 210 to a data collection device 220, e.g., on a periodic basis.

After receiving the data, it is associated with one of the consumer profiles. The association of the received data with one of the consumer profiles includes at least binding (linking) an identification of the consumer profile with an object containing the received data. For instance, the object may be a COSEM object including the received data, while the key identifying the consumer profile is the personal identifier uniquely identifying the utility consumer. It is to be noted, that more than one personal identifier can be used to associate the received data (object) to the consumer profile.

According to a further method step 440, the associated data is stored in a memory, such as memory 320. The storing of the associated data comprises at least storing the data object with the personal identifier in relation with each other. Thus, when the particular data object has to be retrieved from the memory, it may be identified easily by the personal identifier as a key.

While the method steps 410 to 440 only involve one or more utility meters 210 and a data collection device 220, the further method steps involve another entity, such as a head end system 240 or another entity of a consumer provider or billing institution. In the next step 450 a request for utility data is received. According to the request, corresponding associated data is sent back to the requestor at step 460. In case it is determined that the data associated with a personal identifier included in the request is not stored in a memory, the data can be retrieved from a corresponding utility meter out of the plurality of utility meters 210 at step 455.

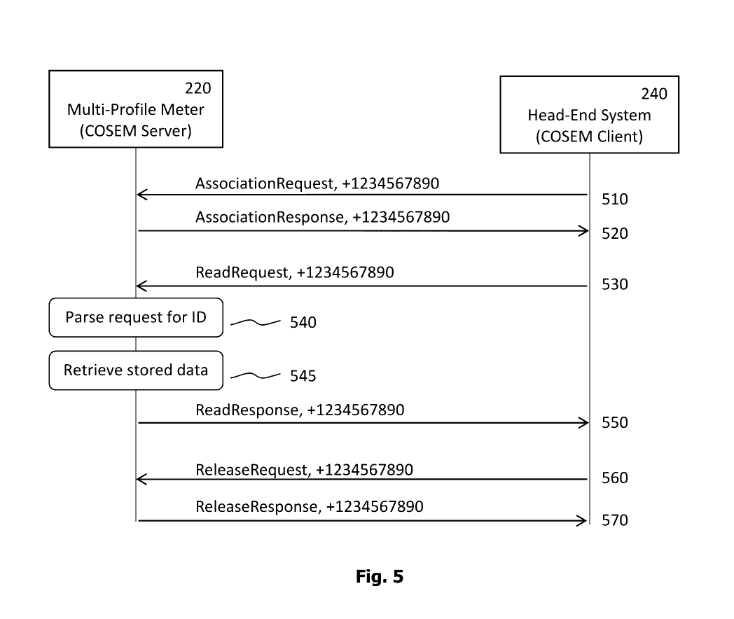

The interaction of the data collection system 220 and head end system entity 240 according to steps 450 to 460 will be explained in more detail with respect to FIG. 5. FIG. 5 illustrates a block diagram schematically illustrating the data exchange between the two entities 220 and 240. This data exchange is described with respect to certain requests and responses between devices 220 and 240. Each request and response may also be referred to as a message, such as a request message or response message, since the request/response includes the exchange (transmission and reception) of data messages between the devices. Thus, the terms “request” and “request message” as well as “response” and “response message” are interchangeable.

Since the data collection system 220 (or multi-profile meter 220) provides data on a request basis, device 220 is considered as a server. For instance, the illustrated multi-profile meter 220 may act as a COSEM server. Correspondingly, the head end system 240 or any other entity related to the head end system, utility provider or billing entity, acts as a client, since it requests data from the multi-profile meter 220. In other words, the head end system 240 may act as a COSEM client, i.e., a client device employing a COSEM model.

At a first step 510, the head end system 240 requests association with the multi-profile meter 220. This association request initiates a session between the devices 220 and 240. It may already include a personal identifier for a consumer (profile) for which the head end system 240 wants to acquire utility meter data. However, the association with the multi-profile meter 220 may take place without a personal identifier.

In the next step 520, the multi-profile meter 220 responds to the association request. For instance, the multi-profile meter 220 may determine, whether the head end system 240 is allowed to request data from the multi-profile meter 220. Furthermore, if a personal identifier is provided with the association request (step 510), the multi-profile meter 220 may also determine whether it is the responsible server for data of this personal identifier. In case that the multi-profile meter 220 acknowledges the association from head end system 240, a session is established between devices 220 and 240.

In response to the successful association the head end system 240 sends a read request to the multi-profile meter 220 in step 530. If the association already included the personal identifier, the read request may not require including the personal identifier. Nevertheless, the read request may again or for the first time include the personal identifier (ID) identifying the consumer for whom data is to be requested. It is noted that the read request may include a plurality of personal identifier to request data of multiple consumer profiles at once.

Accordingly, the multi-profile meter 220 will parse the request for at least one ID (see step 540). Alternatively or additionally, the multi-profile meter 220 will parse any session information for the personal identifier. Based on the personal identifier determined in step 540, the multi-profile meter 220 will retrieve stored data in step 545. The stored data may be retrieved from a memory based on the personal identifier. For instance, the personal identifier may be used as a key to retrieve corresponding data, such as a data object (COSEM object) from the memory.

In a further step 550, the multi-profile meter 220 sends a read response message to the head end system 240. This read response includes the retrieved stored data (from step 545). In addition, the read response message may also include the personal identifier as illustrated in FIG. 5. Here, the personal identifier is optional, since the head end system 240 may be aware of the personal identifier based on session information stored at the head end. In particular, if data for only one consumer is requested in that session, the personal identifier can be omitted in the read response.

Finally, after the data has been received at the head end system 240 entirely, the head end system 240 may send a release request message in step 560 to multi-profile meter 220. The multi-profile meter 220 will accordingly send a release response message to the head end system 240 in step 570. Again, the release request message and release response message of steps 560 and 570, respectively, may include the personal identifier to make sure that the correct session is terminated.

While the method illustrated in FIG. 5 has been described with respect to a single personal identifier, the head end system 240 may request data for more than one consumer. In this case, the association request may identify more than one personal identifier, in order to set up a session for the plurality of personal identifiers (i.e., consumers). Alternatively, the session between head end system 240 and multi-profile meter 220 may be established more general, i.e., without binding the session to one or more personal identifiers. In this case, the read request at step 530 needs to include one or more personal identifiers, so that the multi-profile meter 220 is capable of retrieving the correct stored utility meter data in step 545.

The read request message of step 530 may be sent for each personal identifier. After the head end system 240 has received the read response message (at step 550) the next read request message with another personal identifier is sent to the multi-profile meter 220. When all utility meter data for all consumers has been requested and received, the head end system 240 may release the session at steps 560 and 570.

Also alternatively to the above, the read request in step 530 may include a plurality of personal identifiers. This allows the multi-profile meter 220 to send out one or more read response messages at step 550. This messages (these messages) may either include utility meter data for one personal identifier (one consumer), or may be a burst message with all utility meter data of all requested user profiles (consumers). In case of the first option, more than one read response message at step 550 is sent to head end system 240.

Many advantages of the present disclosure will be fully understood from the foregoing description, and it will be apparent that various changes may be made in the form, construction and arrangement of the units and devices without departing from the scope of the present disclosure and/or without sacrificing all of its advantages. Furthermore, the system according to the present disclosure allows costs savings on individual meter installation, maintenance and upgrade, since there may be only one single meter per facility (complex) which includes the data collection device (multi-profile meter) as explained herein. The individual reading of each utility meter can be avoided, since the head end system is capable of requesting a plurality of utility meter data at once. Moreover, since consumer profiles can be implemented on a software basis, the utility meter reading can be achieved by other commercial entities than the utility provider. For instance, telecommunication operators may associate consumer profiles of a data collection system as described herein with a telephone number of the respective consumer. Thus, using the telephone number (being unique to the consumer) the telecommunication operator is capable of billing utility consumptions together with a telephone bill. This allows new metering opportunities. Demand-response-systems can be supported well with the approach of the present disclosure and can allow efficient usage depending on a device level, user level and residential/commercial complex area level. By integrating consumer profiles into a utility meter system, scenarios where consumers are moving in and out of occupied units and/or move to other areas are easily manageable. Thus, a more on-demand consumption and billing system as well as an enhanced flexibility of the utility meter system can be achieved. Since the present disclosure can be varied in many ways, it will be recognized that the present disclosure should be limited only by the scope of the following claims.

What is claimed is:

1. A data collection device for use in a utility meter system, the device comprising:
a data communication circuit configured to receive data from one of a plurality of utility meters;
a memory configured to store data; and
a data processing circuit configured to manage and store multiple utility consumer profiles, each of the profiles being identifiable by a unique personal identifier of the respective utility consumer, to associate the received data to one of the profiles, and to write the associated data into the memory.

2. The data collection device of claim 1, wherein the data processing circuit is configured to, when associating the data, generate at least one COSEM object including the received data and map the COSEM object to the personal identifier.

3. The data collection device of claim 1, wherein the data communication circuit is further configured to transmit the associated data stored in the memory to a head end entity of the utility meter system.

4. The data collection device of claim 3, wherein the data communication circuit is configured to transmit the associated data to the head end entity upon receiving a request for the associated data from the head end entity, wherein the request includes the personal identifier of at least one utility consumer.

5. The data collection device of claim 4, wherein the data processing circuit is further configured to parse the request, to determine the at least one personal identifier, and to retrieve the associated data from the memory based on the determined at least one personal identifier.

6. The data collection device of claim 4, wherein the data processing circuit is further configured to determine whether associated data corresponding to the personal identifier included in the request is stored in the memory and, if the associated data is not stored in the memory, control the data communication circuit to retrieve the data from a corresponding utility meter out of the plurality of utility meters.

7. The data collection device of claim 1, wherein the data processing circuit is further configured to initiate the receiving of data from the one of the plurality of utility meters.

8. The data collection device of claim 1, wherein the received data is utility meter data representing a consumption of electric power, gas and/or water.

9. The data collection device of claim 1, wherein the personal identifier is a phone number of the utility consumer, a Mobile Station International Subscriber Directory Number (MSISDN) of the utility consumer, or a public Internet Protocol (IP) address of the utility consumer.

10. A utility meter comprising the data collection device of claim 1.

11. A head end system of a utility meter system comprising the data collection device of claim 1.

12. A utility meter system comprising:
a plurality of utility meters;
a head end system; and
the data collection device of claim 1.

13. The utility meter system of claim 12, wherein the head end system is configured to start and end a data request session with the data collection device, wherein the session is bound to at least one personal identifier identifying at least one respective utility customer for whom data is to be requested.

14. The utility meter system of claim 12, wherein the head end system and the data collection device are configured to communicate according to the DLMS standard.

15. The utility meter system of claim 12, wherein the data collection device is configured to collect data of utility meters installed in one residential complex or one commercial complex.

16. A method of data collection in a utility meter system, the method comprising:
managing multiple utility consumer profiles, each of the profiles being identifiable by a unique personal identifier of a respective utility consumer;
receiving data from one of a plurality of utility meters;
associating the received data to one of the profiles; and
storing the associated data in a memory.

17. The method of claim 16, wherein associating the data comprises generating at least one COSEM object including the received data and mapping the COSEM object to the personal identifier.

18. The method of claim 16, further comprising:
transmitting the associated data to a head end entity of the utility meter system.

19. The method of claim 18, further comprising:
receiving a request for the associated data from the head end entity, wherein the request includes the personal identifier of at least one utility consumer.

20. The method of claim 19, further comprising:
parsing the request;
determining the at least one personal identifier from the request; and
retrieving the associated data from the memory based on the determined at least one personal identifier.

21. The method of claim 17, further comprising:
determining whether associated data corresponding to the personal identifier included in the request is stored in the memory; and
if the associated data is not stored in the memory, retrieving the data from a corresponding utility meter out of the plurality of utility meters.

22. The method of claim 16, further comprising:
initiating the receiving of data from the one of the plurality of utility meters.

23. The method of claim 16, wherein the received data is utility meter data representing a consumption of electric power, gas and/or water.

24. A non-transitory computer-readable medium comprising, stored thereupon, a computer program comprising program code portions configured so as to cause a computer system executing the program code portions to:
manage multiple utility consumer profiles, each of the profiles being identifiable by a unique personal identifier of a respective utility consumer;
receive data from one of a plurality of utility meters;
associate the received data to one of the profiles; and
